(19) United States
(12) Patent Application Publication
(10) Pub. No.: US 2025/0374598 A1
(43) Pub. Date: Dec. 4, 2025

(54) SEMICONDUCTOR DEVICE

(71) Applicant: Japan Display Inc., Tokyo (JP)

(72) Inventors: Hajime WATAKABE, Tokyo (JP); Masashi TSUBUKU, Tokyo (JP); Kentaro MIURA, Tokyo (JP); Masahiro WATABE, Tokyo (JP); Hitoshi TANAKA, Tokyo (JP)

(73) Assignee: Japan Display Inc., Tokyo (JP)

(21) Appl. No.: 19/216,737

(22) Filed: May 23, 2025

(30) Foreign Application Priority Data
May 29, 2024 (JP) 2024-087258
Apr. 28, 2025 (JP) 2025-074201

(51) Int. Cl. H10D 30/67; H10D 86/40; H10D 86/60

(52) U.S. Cl. CPC H10D 30/6723; H10D 30/6736; H10D 30/6737; H10D 30/6755; H10D 30/6757; H10D 86/423; H10D 86/60

(57) ABSTRACT

A semiconductor device includes: an oxide semiconductor layer having a pattern; a gate electrode facing the oxide semiconductor layer; a gate insulating layer provided between the oxide semiconductor layer and the gate electrode; a first insulating layer provided above the gate electrode and having a first opening overlapping a pattern edge portion of the oxide semiconductor layer in a plan view; and a first electrode provided above the first insulating layer and inside the first opening, and contacting the oxide semiconductor layer so as to cover the pattern edge portion of the oxide semiconductor layer in a bottom part of the first opening.

### CROSS-REFERENCE TO RELATED APPLICATIONS

This application claims the benefit of priority to Japanese Patent Application No. 2024-087258, filed on May 29, 2024 and Japanese Patent Application No. 2025-074201, filed on Apr. 28, 2025, the entire contents of each are incorporated herein by reference.

### FIELD

One embodiment of the present invention relates to a semiconductor device.

### BACKGROUND

Recently, a transistor using an oxide semiconductor as a channel has been developed in place of an amorphous silicon, a low-temperature polysilicon, and a single-crystal silicon (e.g., Japanese laid-open patent publication No. 2014-146819 and Japanese laid-open patent publication No. 2015-159315). The transistor using the oxide semiconductor as the channel is formed in a simple-structured, low-temperature process similar to a transistor using an amorphous silicon as a channel. It is known that the transistor using the oxide semiconductor as the channel has higher mobility than the transistor using the amorphous silicon as the channel and has a very low off-current.

In recent years, due to the advancement in the technology for reducing the size of a pixel in modern display devices, it has also become possible to reduce the width of wiring and the size of transistors. However, there is a limitation to these reductions, and an aperture ratio is reduced due to arrangements of a metal layer and a semiconductor layer constituting a pixel circuit. Therefore, the development for using the oxide semiconductor layer as the channel of the transistor in the pixel circuit, which obtains sufficient characteristics in spite of its miniaturized size is progressing.

In order to reduce a pixel size without reducing the aperture ratio, it is necessary to improve a layout of the pixel circuit and a structure of the transistor of the pixel circuit. On the other hand, the transistor of the pixel circuit is required to have good initial characteristic and reliability in a stress test.

### SUMMARY

A semiconductor device according to an embodiment of the present disclosure includes: an oxide semiconductor layer having a pattern; a gate electrode facing the oxide semiconductor layer; a gate insulating layer provided between the oxide semiconductor layer and the gate electrode; a first insulating layer provided above the gate electrode and having a first opening overlapping a pattern edge portion of the oxide semiconductor layer in a plan view; and a first electrode provided above the first insulating layer and inside the first opening, and contacting the oxide semiconductor layer so as to cover the pattern edge portion of the oxide semiconductor layer in a bottom part of the first opening.

### BRIEF DESCRIPTION OF DRAWINGS

FIG. 1 is a cross-sectional view showing an outline of a display device according to an embodiment of the present invention.

FIG. 2 is a plan view showing an outline of a display device according to an embodiment of the present invention.

FIG. 3 is a plan view showing a layout of each layer in a display device according to an embodiment of the present invention.

FIG. 4 is a plan view showing a layout of one or more layers in a display device according to an embodiment of the present invention.

FIG. 5 is a plan view showing a layout of one or more layers in a display device according to an embodiment of the present invention.

FIG. 6 is a plan view showing a layout of one or more layers in a display device according to an embodiment of the present invention.

FIG. 7 is a plan view showing a layout of one or more layers in a display device according to an embodiment of the present invention.

FIG. 8 is a plan view showing a layout of one or more layers in a display device according to an embodiment of the present invention.

FIG. 9 is a plan view showing a layout of one or more layers in a display device according to an embodiment of the present invention.

FIG. 10 is a plan view showing a layout of one or more layers in a display device according to an embodiment of the present invention.

FIG. 11 is a plan view showing a layout of one or more layers in a display device according to an embodiment of the present invention.

FIG. 12 is a plan view showing a layout of one or more layers in a display device according to an embodiment of the present invention.

FIG. 13 is a plan view showing a layout of one or more layers in a display device according to an embodiment of the present invention.

FIG. 14 is a cross-sectional view showing a structure of a semiconductor device according to an embodiment of the present invention.

FIG. 15 is a plan view showing a structure of a semiconductor device according to an embodiment of the present invention.

FIG. 16 is a plan view showing an overview of a display device according to an embodiment of the present invention.

FIG. 17 is a block diagram showing a circuit configuration of a display device according to an embodiment of the present invention.

FIG. 18 is a circuit diagram showing a pixel circuit of a display device according to an embodiment of the present invention.

FIG. 19 is a cross-sectional view showing a structure of a semiconductor device according to a comparative example.

### DESCRIPTION OF EMBODIMENTS

Embodiments of the present invention will be described below with reference to the drawings. The following disclosure is merely an example. A configuration that can be easily conceived by a person skilled in the art by appropriately changing the configuration of the embodiment while maintaining the gist of the invention is naturally included in the scope of the present invention. For the sake of clarity of description, the drawings may be schematically represented with respect to widths, thicknesses, shapes, and the like of the respective portions in comparison with actual embodiments. However, the shape shown is merely an example and does not limit the interpretation of the present invention. In this specification and each of the drawings, the same symbols are assigned to the same components as those described previously with reference to the preceding drawings, and a detailed description thereof may be omitted as appropriate.

In the embodiments of the present invention, a direction from a substrate to an oxide semiconductor layer is referred to as upper or above. On the contrary, a direction from the oxide semiconductor layer to the substrate is referred to as lower or below. As described above, for convenience of explanation, although the phrase “above” or “below” is used for explanation, for example, a vertical relationship between the substrate and the oxide semiconductor layer may be arranged in a different direction from that shown in the drawing. In the following description, for example, the expression “the oxide semiconductor layer on the substrate” merely describes the vertical relationship between the substrate and the oxide semiconductor layer as described above, and other members may be arranged between the substrate and the oxide semiconductor layer. Above or below means a stacking order in a structure in which multiple layers are stacked, and when it is expressed as a pixel electrode above a transistor, it may be a positional relationship where the transistor and the pixel electrode do not overlap each other in a plan view. On the other hand, when it is expressed as a pixel electrode vertically above a transistor, it means a positional relationship where the transistor and the pixel electrode overlap each other in a plan view.

“Display device” refers to a structure configured to display an image using electro-optic layers. For example, the term display device may refer to a display panel including the electro-optic layer, or it may refer to a structure in which other optical members (e.g., polarizing member, backlight, touch panel, etc.) are attached to a display cell. The “electro-optic layer” can include a liquid crystal layer, an electroluminescence (EL) layer, an electrochromic (EC) layer, and an electrophoretic layer, as long as there is no technical contradiction. Therefore, although the embodiments described later will be described by exemplifying the liquid crystal display device including a liquid crystal layer as the display device, the structure in the present embodiment can be applied to a display device including the other electro-optical layers described above.

The expressions “a includes A, B, or C,” “α includes any of A, B, or C,” and “α includes one selected from a group consisting of A, B, and C” do not exclude the case where a includes multiple combinations of A to C unless otherwise specified. Furthermore, these expressions do not exclude the case where α includes other elements.

The following embodiments may be combined with each other as long as there is no technical contradiction.

An object of one embodiment of the present invention is to realize a semiconductor device having good electrical characteristics without reducing an aperture ratio even in a fine pixel circuit.

### 1. First Embodiment

### [1-1. Configuration of Display Device 10]

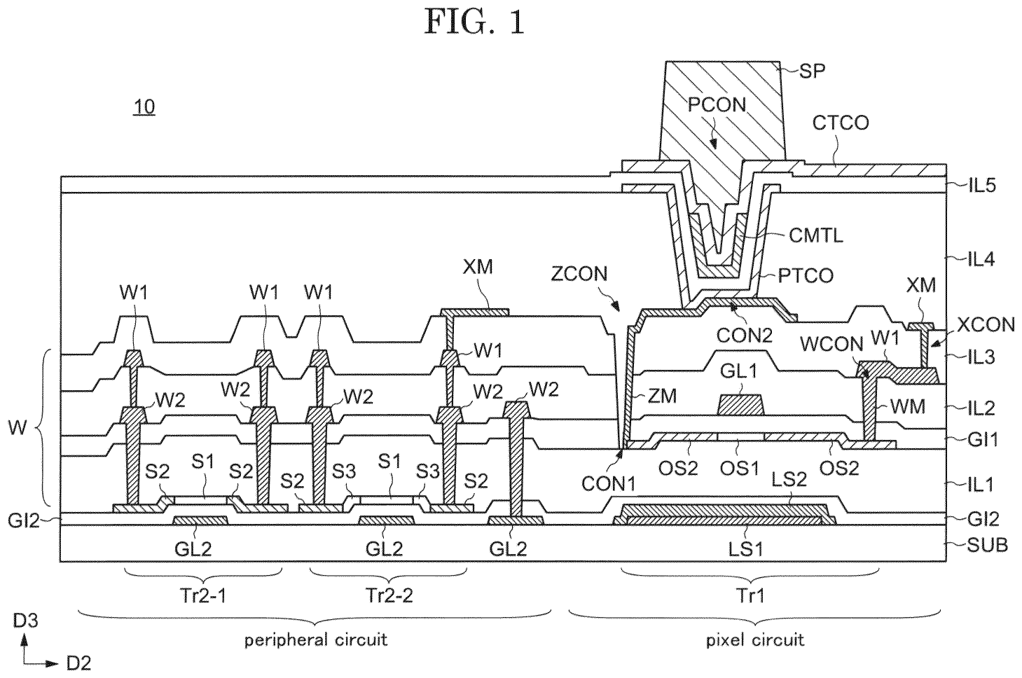

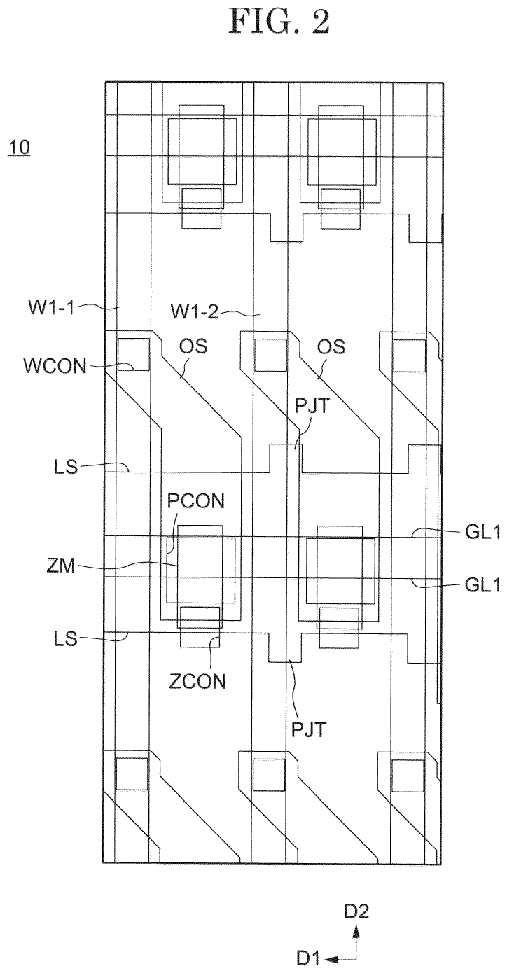

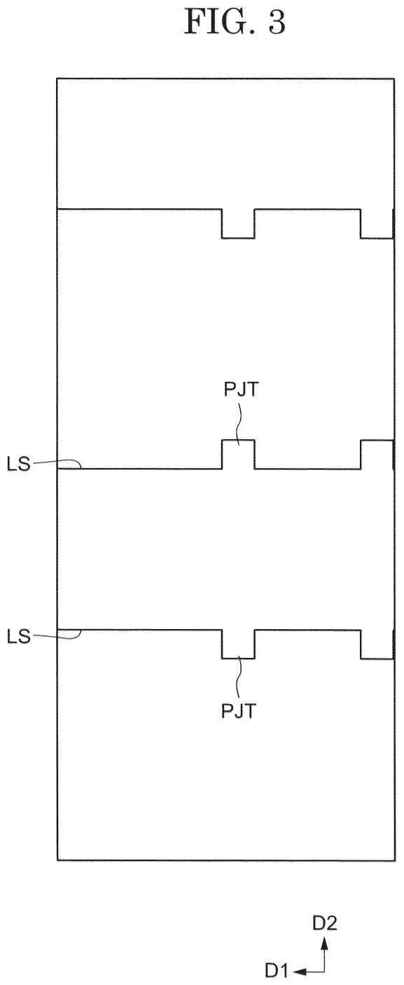

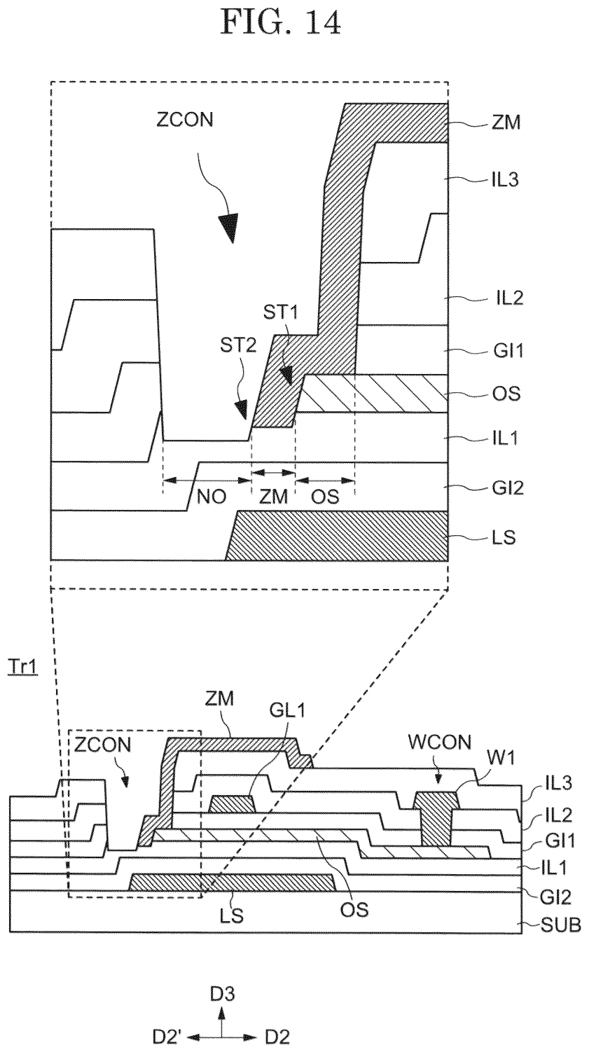

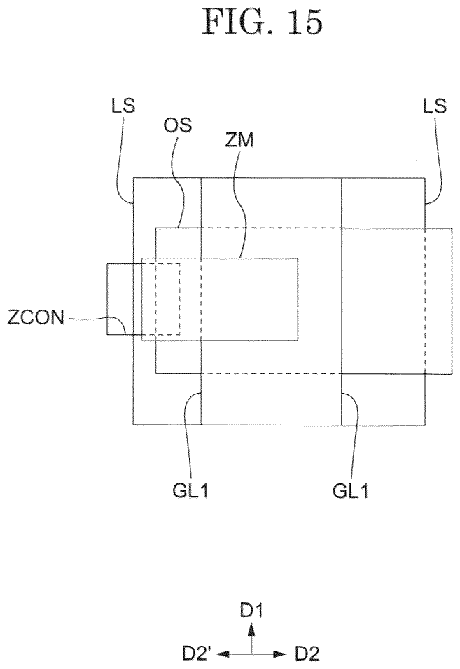

A configuration of a display device 10 according to an embodiment of the present invention will be described with reference to FIG. 1 to FIG. 15. FIG. 1 is a cross-sectional view showing an outline of a display device according to an embodiment of the present invention. FIG. 2 is a plan view showing an outline of a display device according to an embodiment of the present invention. FIG. 3 to FIG. 13 are plan views showing layouts of each layer in a display device according to an embodiment of the present invention. FIG. 14 is a cross-sectional view showing a semiconductor device according to an embodiment of the present invention. FIG. 15 is a plan view showing a semiconductor device according to an embodiment of the present invention. The cross-sectional view in FIG. 1 is for explaining a layer structure of the display device 10, which may not exactly match the plan view in FIG. 2.

As shown in FIG. 1, the display device 10 includes a substrate SUB. The display device 10 also includes a transistor Tr1, a transistor Tr2 (Tr2-1 and Tr2-2), a wiring W (W1 and W2), a pixel electrode PTCO, a common auxiliary electrode CMTL, and a common electrode CTCO on the substrate SUB. TCO is an abbreviation for Transparent Conductive Oxide. The transistor Tr1 is a semiconductor device included in a pixel circuit of the display device 10. The transistor Tr2 is a semiconductor device included in a peripheral circuit. As will be described in detail later, the peripheral circuit is a circuit configured to drive the pixel circuit. In the following explanation, “semiconductor device” may include only a configuration of the transistor Tr1, and may include both configurations of the transistor Tr1 and Tr2.

### [1-2. Configuration of Transistor Tr1]

The transistor Tr1 includes an oxide semiconductor layer OS (OS1 and OS2), a gate insulating layer GI1, a gate electrode GL1, a connecting electrode ZM, a connecting electrode WM and a wiring XM. The gate electrode GL1 faces the oxide semiconductor layer OS. The gate insulating layer GI1 is provided between the oxide semiconductor layer OS and the gate electrode GL1. In the present embodiment, although a top gate type transistor in which the oxide semiconductor layer OS is provided closer to the substrate SUB than the gate electrode GL1 is exemplified, a bottom gate type transistor in which a positional relationship between the gate electrode GL1 and the oxide semiconductor layer OS is reversed may be applied.

The oxide semiconductor layer OS includes oxide semiconductor layers OS1, OS2. The oxide semiconductor layer OS1 is an oxide semiconductor layer in a region overlapping the gate electrode GL1 in a plan view. The oxide semiconductor layer OS1 functions as a semiconductor layer and is switched between a conductive state and a non-conductive state according to a voltage supplied to the gate electrode GL1. That is, the oxide semiconductor layer OS1 functions as a channel for the transistor Tr1. The oxide semiconductor layer OS2 functions as a conductive layer. The oxide semiconductor layers OS1, OS2 are layers formed from the same oxide semiconductor layer. For example, the oxide semiconductor layer OS2 is a low resistance oxide semiconductor layer formed by implanting impurities into a layer which has the same physical properties as the oxide semiconductor layer OS1.

An insulating layer IL2 is arranged above the gate electrode GL1. A wiring W1 is arranged above the insulating layers IL2. The wiring W1 is connected to the oxide semiconductor layer OS2 via a connection electrode WM provided inside the opening WCON provided in the insulating layer IL2 and the gate insulating layer GI1. The opening WCON overlaps a pattern of the oxide semiconductor layer OS in a plan view. In the present embodiment, the opening WCON is located inside the pattern of the oxide semiconductor layer OS in the plan view (see FIG. 2). The connection electrode WM is in contact with the oxide semiconductor layer OS at a bottom of the opening WCON. The wiring W1 and the connection electrode WM are metal layers and are the same layer. A data signal related to gradation of the pixel is transmitted to the wiring W1. An insulating layer IL3 is arranged above the insulating layer IL2 and the wiring W1. In other words, the wiring W1 is arranged between the insulating layer IL2 and the insulating layer IL3. Similarly, the insulating layer IL2 is arranged between the insulating layer IL3 and the oxide semiconductor layer OS. The connection electrode ZM and the wiring XM are in contact with an upper surface of the insulating layer IL3 above the insulating layer IL3. In other words, the insulating layer IL3 is in contact with lower surfaces of the connection electrode ZM and the wiring XM below the connection electrode ZM and the wiring XM.

The connecting electrode ZM is connected to the oxide semiconductor layer OS2 via an opening ZCON provided in the gate insulating layer GI1 and the insulating layers IL3 and IL2. The connecting electrode ZM is in contact with the oxide semiconductor layer OS2 at a bottom portion of the opening ZCON. The wiring XM is connected to the wiring W1 via an opening XCON provided in the insulating layer IL3. The connecting electrodes WM and ZM and the wiring XM are metal layers. As described above, the gate electrode GL1, the connecting electrode ZM, and the wiring XM are provided above the oxide semiconductor layers OS. A connection structure between the oxide semiconductor layer OS2 and the connecting electrode ZM in the opening ZCON will be described in detail later.

The connection electrode ZM may be referred to as a “first electrode.” The wiring W1 and the connection electrode WM may be referred to as a “second electrode.” The wiring XM is arranged in the same layer as the connection electrode ZM and is separated from the connection electrode ZM. A material of the connection electrode ZM is the same as a material of the wiring XM.

The insulating layer IL3 may be referred to as a “first insulating layer.” The insulating layer IL1 may be referred to as a “second insulating layer.” The insulating layer IL2 may be referred to as a “third insulating layer.” The opening ZCON may be referred to as a “first opening.” The opening WCON may be referred to as a “second opening.”

An insulating layer IL4 is provided above the connecting electrode ZM. The insulating layer IL4 eases (flattens) a step formed from a structure provided below the insulating layer IL4. The insulating layer IL4 may be referred to as a planarization film. The pixel electrode PTCO is provided above the insulating layer IL4. The pixel electrode PTCO is connected to the connecting electrode ZM via an opening PCON provided in the insulating layer IL4. A region where the connecting electrode ZM and the pixel electrode PTCO are in contact with each other is referred to as a contact region CON2. The contact region CON2 overlaps the gate electrode GL1 in a plan view. The pixel electrode PTCO is a transparent conductive layer.

An insulating layer IL5 is provided above the pixel electrode PTCO. The common auxiliary electrode CMTL and the common electrode CTCO are provided above the insulating layer IL5. That is, the pixel electrode PTCO faces the common electrode CTCO via the insulating layer IL5. The common electrode CTCO is connected to the common auxiliary electrode CMTL at the opening PCON. As will be described in detail later, the common auxiliary electrode CMTL and the common electrode CTCO have different patterns respectively when seen in a plan view. The common auxiliary electrode CMTL is a metal layer. The common electrode CTCO is a transparent conductive layer. The electric resistance of the common auxiliary electrode CMTL is lower than the electric resistance of the common electrode CTCO. The common auxiliary electrode CMTL also functions as a light-shielding layer. For example, the common auxiliary electrode CMTL shields light from adjacent pixels to suppress an occurrence of color mixing. A spacer SP is provided above the common electrode CTCO.

The spacer SP is provided for a part of the pixels. For example, the spacer SP may be provided for any one of a blue pixel, a red pixel and a green pixel. However, the spacer SP may be provided for all the pixels. A height of the spacer SP is half the height of a cell gap. A spacer is also provided on a counter substrate, and the spacer on the counter substrate and the above spacer SP overlap in a plan view.

A light-shielding layer LS is provided between the transistor Tr1 and the substrate SUB. In the present embodiment, light-shielding layers LS1, LS2 are provided as the light-shielding layer LS. However, the light-shielding layer LS may be formed of only the light-shielding layer LS1 or LS2. In a plan view, the light-shielding layer LS is provided in a region where the gate electrode GL1 and the oxide semiconductor layer OS overlap. That is, in a plan view, the light-shielding layer LS is provided in a region overlapping the oxide semiconductor layer OS1. The light-shielding layer LS suppresses the light incident from the substrate SUB side from reaching the oxide semiconductor layer OS1. In the case where a conductive layer is used as the light-shielding layer LS, a voltage may be applied to the light-shielding layer LS to control the oxide semiconductor layer OS1. In the case where a voltage is applied to the light-shielding layer LS, the light-shielding layer LS and the gate electrode GL1 may be connected by a peripheral region of the pixel circuit.

The insulating layer IL1 and the gate insulating layer GI2 are provided between the light-shielding layer LS and the oxide semiconductor layer OS. In the present embodiment, although a configuration in which the oxide semiconductor layer OS is in contact with the insulating layer IL1 has been exemplified, the configuration is not limited to this configuration. For example, a metal oxide layer may be provided between the oxide semiconductor layer OS and the insulating layer IL1. For example, a metal oxide containing aluminum as a main component may be used as the metal oxide layer. Specifically, aluminum oxide may be used as the metal oxide layer. Here, the metal oxide layer may be provided in the same region as the insulating layer IL1, or may be processed into the same pattern as the oxide semiconductor layer OS.

### [1-3. Configuration of Transistor Tr2]

The transistor Tr2 has a p-type transistor Tr2-1 and an n-type transistor Tr2-2.

The p-type transistor Tr2-1 and the n-type transistor Tr2-2 both include a gate electrode GL2, a gate insulating layer GI2, and a semiconductor layer S (S1 to S3). The gate electrode GL2 faces the semiconductor layer S. The gate insulating layer GI2 is provided between the semiconductor layer S and the gate electrode GL2. In the present embodiment, although a bottom gate type transistor in which the gate electrode GL2 is provided closer to the substrate SUB than the semiconductor layer S is exemplified, a top gate type transistor in which a positional relationship between the semiconductor layer S and the gate electrode GL2 is reversed may be used as the display device.

The semiconductor layer S of the p-type transistor Tr2-1 includes semiconductor layers S1 and S2. The semiconductor layer S of the n-type transistor Tr2-2 includes the semiconductor layers S1, S2 and S3. The semiconductor layer S1 is a semiconductor layer overlapping the gate electrode GL2 in a plan view. The semiconductor layer S1 functions as a channel for the transistors Tr2-1 and Tr2-2. The semiconductor layer S2 functions as a conductive layer. The semiconductor layer S3 functions as a conductive layer with a higher resistance than the semiconductor layer S2. The semiconductor layer S3 suppresses hot carrier degradation by attenuating hot carriers intruding toward the semiconductor layer S1.

The insulating layer IL1 and the gate insulating layer GI1 are provided on the semiconductor layer S. In the transistor Tr2, the gate insulating layer GI1 simply functions as an interlayer film. A wiring W2 is provided above these insulating layers. The wiring W2 is connected to the semiconductor layer S via an opening provided in the insulating layer IL1 and the gate insulating layer GI1. The insulating layer IL2 is provided on the wiring W2. The wiring W1 is provided on the insulating layer IL2. The wiring W1 is connected to the wiring W2 via an opening provided in the insulating layer IL2. The insulating layer IL3 is provided above the wiring W1. The wiring XM is provided above the insulating layers IL3. The wiring XM is connected to the wiring W1 through an opening provided in the insulating layers IL3.

The gate electrode GL2 and the light-shielding layer LS2 are the same layer. The wiring W2 and the gate electrode GL1 are the same layer. The same layer means that multiple members are formed from one patterned layer.

### [1-4. Plane Layout of Display Device 10]

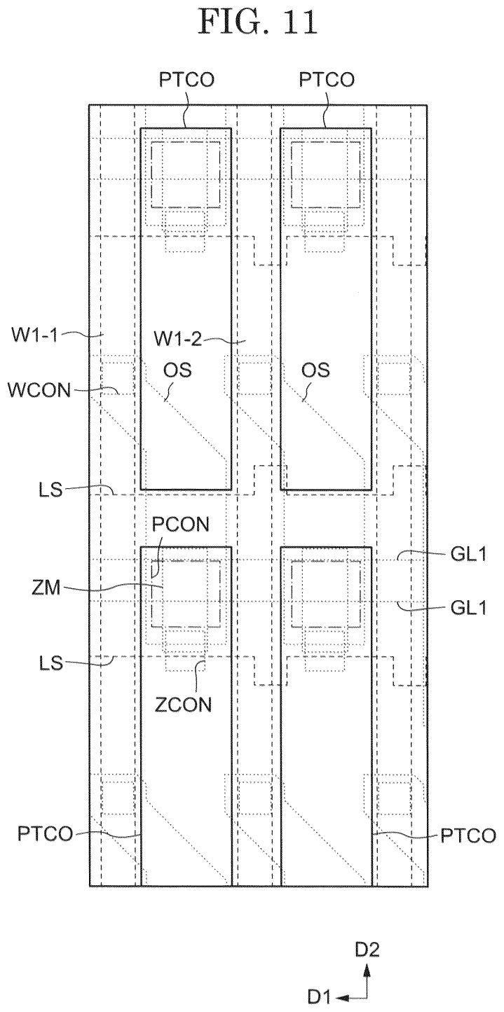

A plane layout of a pixel of the display device 10 will be described with reference to FIG. 2 to FIG. 13. In FIG. 2, the pixel electrode PTCO, the common auxiliary electrode CMTL, the common electrode CTCO, and the spacer SP are omitted. The plane layout of the pixel electrode PTCO, the common auxiliary electrode CMTL, and the common electrode CTCO are shown in FIG. 11 to FIG. 13, respectively.

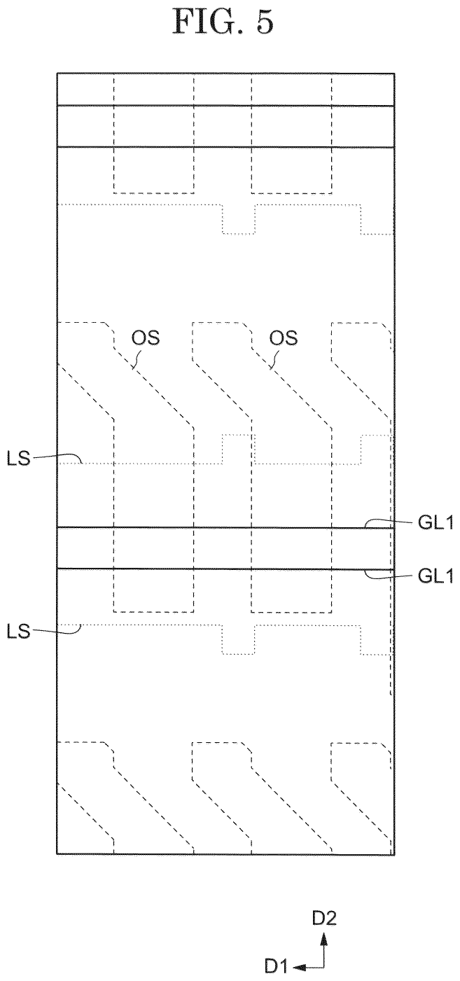

As shown in FIG. 2 and FIG. 3, the light-shielding layer LS extends in a direction D1. A shape of the light-shielding layer LS may be different depending on the pixel. In the present embodiment, a protruding part PJT protruding in a direction D2 is provided from a part of the light-shielding layer LS extending in the direction D1. As shown in FIG. 5, the light-shielding layer LS is provided in a region including the region where the gate electrode GL1 and the oxide semiconductor layer OS overlap in a plan view. The gate electrode GL1 can also be referred to as a “gate line.”

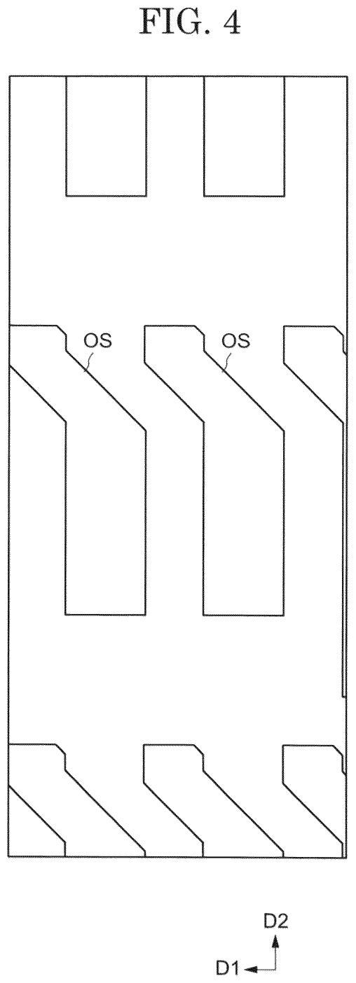

As shown in FIG. 2, FIG. 4, and FIG. 5, the oxide semiconductor layer OS extends in the direction D2. The gate electrode GL1 extends in the direction D1 so as to intersect the oxide semiconductor layer OS. A pattern of the gate electrode GL1 is provided inside a pattern of the light-shielding layer LS. In other words, the oxide semiconductor layers OS is formed in a long shape (a shape having a longitudinal) intersecting the gate electrode GL1.

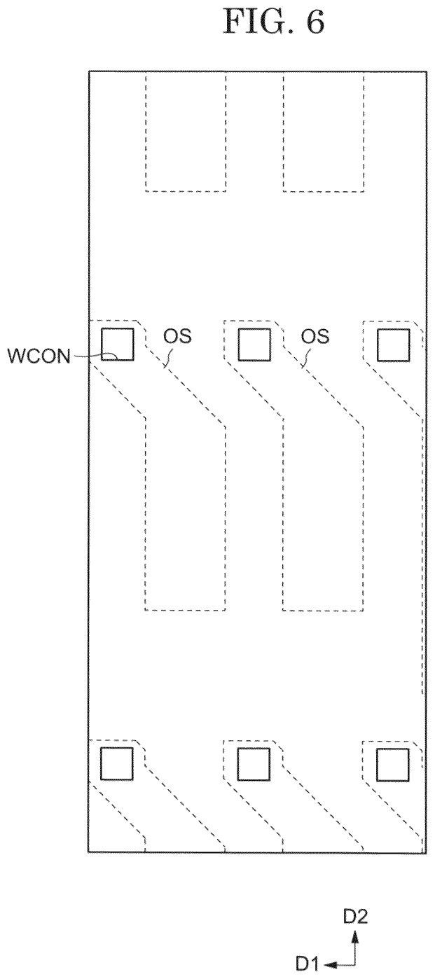

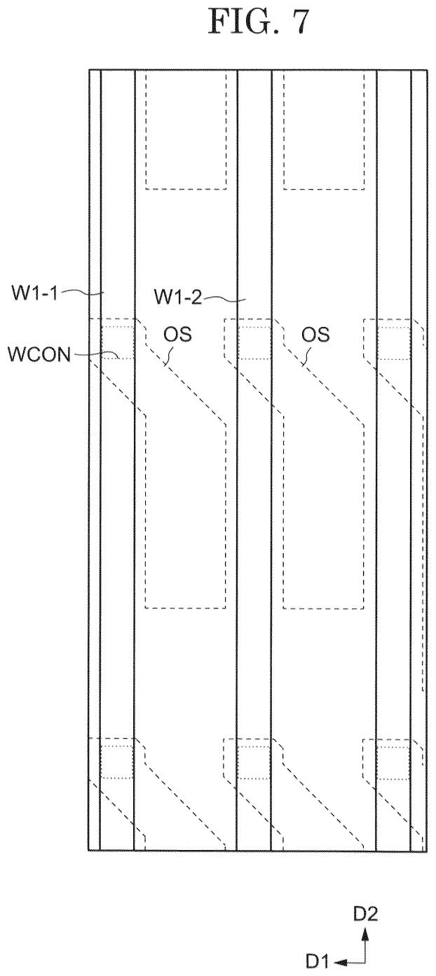

As shown in FIG. 2, FIG. 6, and FIG. 7, the opening WCON is provided in a region overlapping the wiring W1 (W1-1 and W1-2) near an upper end of the pattern of the oxide semiconductor layer OS. A main part of the pattern of the oxide semiconductor layer OS extends in the direction D2 between a pair of the adjacent wirings W1 (W1-1 and W1-2). The remaining part of the pattern of the oxide semiconductor layer OS extends obliquely in the direction D1 and the direction D2 from the main part and overlaps the opening WCON.

As shown in FIG. 2 and FIG. 7, multiple wirings W1 extend in the direction D2. In the case where the adjacent wirings W1 need to be described separately, the adjacent wiring W1 is referred to as a wiring W1-1 and a wiring W1-2. In this case, it can be said that the main part of the oxide semiconductor layer OS extends in the direction D2 between the wiring W1-1 and the wiring W1-2, and intersects the gate electrode GL1. In other words, the oxide semiconductor layer OS is provided in a long shape in the direction D2 and connected to the wiring W1-1 at one end in a longitudinal direction of the oxide semiconductor layer OS.

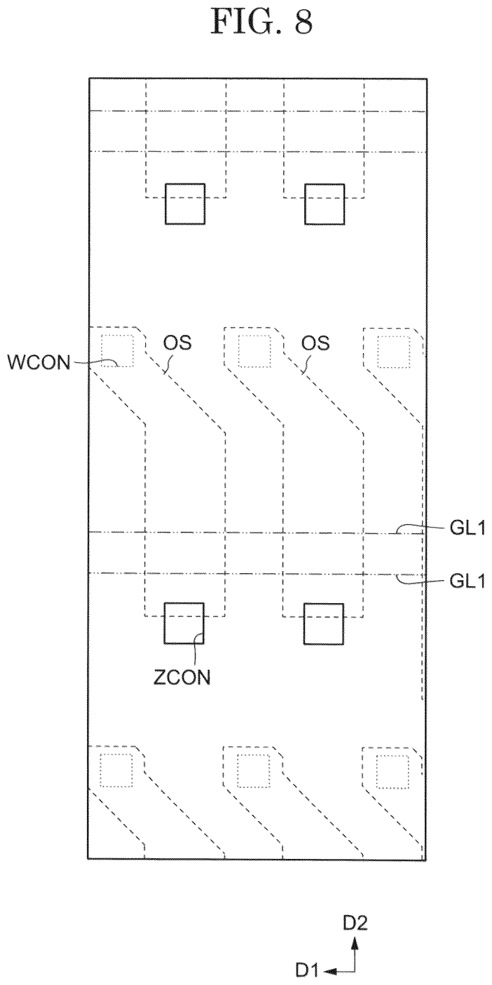

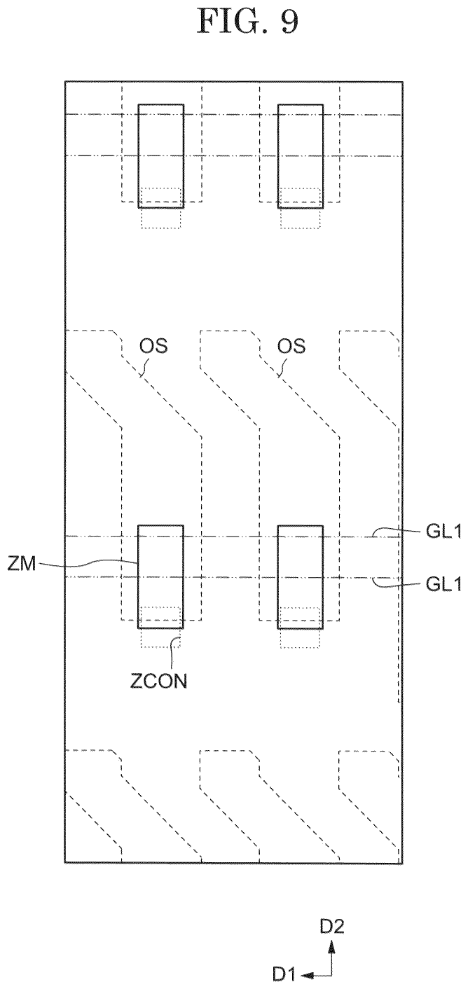

As shown in FIG. 2, FIG. 8, and FIG. 9, the opening ZCON is provided near a lower end of the pattern of the oxide semiconductor layer OS. The opening ZCON is provided in a region overlapping a bottom edge part of the pattern of the oxide semiconductor layer OS and not overlapping the gate electrode GL1. The opening ZCON is provided in a region overlapping the connecting electrode ZM. The connecting electrode ZM overlaps the gate electrode GL1 and the oxide semiconductor layer OS between the wiring W1-1 and the wiring W1-2. The connecting electrode ZM is in contact with the oxide semiconductor layer OS in the opening ZCON not overlapping the gate electrode GL1.

The oxide semiconductor layer OS overlaps a portion of the opening ZCON. Similarly, the connection electrode ZM overlaps a portion of the opening ZCON. Inside a pattern of the opening ZCON, the oxide semiconductor layer OS and the connection electrode ZM are in contact with each other in a region where the oxide semiconductor layer OS and the connection electrode ZM overlap each other. As will be described later, inside the pattern of the opening ZCON, in a region where the oxide semiconductor layer OS and the connection electrode ZM do not overlap each other, the insulating layer IL1 arranged below the oxide semiconductor layer OS and the insulating layer IL4 arranged above the connection electrode ZM are in contact with each other.

In other words, the oxide semiconductor layer OS is connected to the connecting electrode ZM at the other end in the longitudinal direction of the oxide semiconductor layer OS. The connecting electrode ZM is formed in a long shape extending in the direction D2 similar to the oxide semiconductor layer OS. In the direction D1, a width of the connecting electrode ZM is smaller than a width of the oxide semiconductor layer OS.

As shown in FIG. 2, FIG. 7, and FIG. 8, the oxide semiconductor layer OS is in contact with the wiring W1 at the opposite side of the opening ZCON with respect to the gate electrode GL1. A part of the opening ZCON overlaps the light-shielding layer LS.

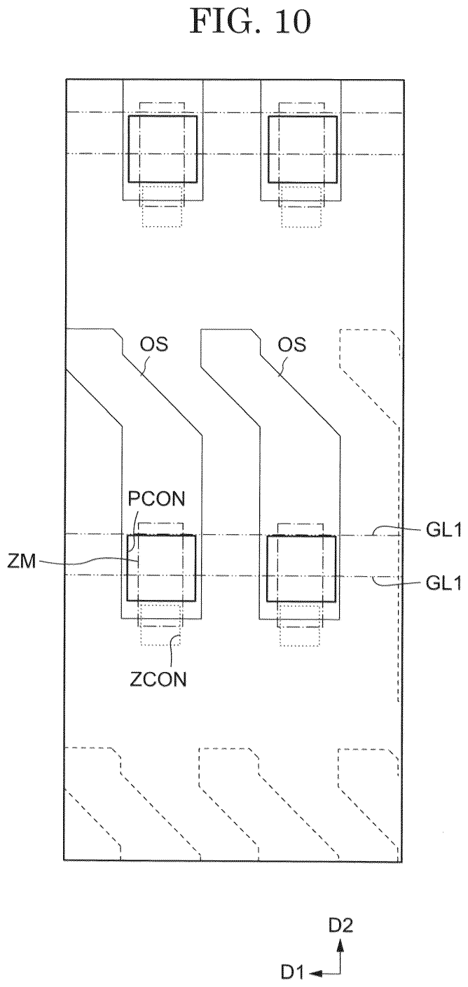

As shown in FIG. 2, FIG. 10, and FIG. 11, the opening PCON is provided near an upper end of a pattern of the connecting electrode ZM. The opening PCON is provided in a region overlapping the pattern of the gate electrode GL1 and the pattern of the connecting electrode ZM. The opening PCON is provided in a region overlapping the pixel electrode PTCO. The pixel electrode PTCO overlaps the gate electrode GL1, the oxide semiconductor layer OS, and the connecting electrode ZM between the wiring W1-1 and the wiring W1-2. Therefore, the pixel electrode PTCO is in contact with the connecting electrode ZM in the opening PCON overlapping the gate electrode GL1.

The pixel electrode PTCO extends in a translucent region as described below. In other words, the pixel electrode PTCO is formed in a long shape extending in the direction D2 similar to the oxide semiconductor layer OS and the wiring W1-1. In the direction D1, a width of the pixel electrode PTCO is larger than the width of the oxide semiconductor layer OS at a part where the opening PCON is provided.

As shown in FIG. 11, the connecting electrode ZM is formed in a long shape extending along the wiring W1-1. In the direction D1, a width of the opening PCON constituting the contact region CON2 is larger than the width of the connecting electrode ZM. The connecting electrode ZM entirely overlaps the pixel electrode PTCO in a plan view.

As shown in FIG. 11, the pixel electrodes PTCO are aligned in the direction D2. Of the pixels adjacent in the direction D2, one pixel may be referred to as a “first pixel,” and the other pixel may be referred to as a “second pixel.” For example, the first pixel is a pixel corresponding to the upper pixel electrode PTCO among the pixel electrodes PTCO aligned in the direction D2 in FIG. 11, and the second pixel is a pixel corresponding to the lower pixel electrode PTCO among the pixel electrodes PTCO aligned in the direction D2 in FIG. 11. In this case, the first pixel and the second pixel are supplied with a pixel signal from the wiring W1-1.

In addition, the pixel electrodes PTCO are aligned in the direction D1. A pixel adjacent in the direction D1 with respect to the above first pixel is referred to as a “third pixel,” and a pixel adjacent in the direction D1 with respect to the second pixel is referred to as a “fourth pixel.” The third pixel and the fourth pixel are adjacent to each other in the direction D2. The third pixel and the fourth pixel are supplied with the pixel signal from the wiring W1-2 adjacent to the wiring W1-1.

As described above, each of the first pixel, the second pixel, the third pixel, and the fourth pixel includes the transistor Tr1 (pixel transistor), the connecting electrode ZM, and the pixel electrode PTCO.

As described above, the transistor Tr1 includes the oxide semiconductor layer OS, the gate electrode GL1 facing the oxide semiconductor layer OS, and the gate insulating layer GI1 between the oxide semiconductor layer OS and the gate electrode GL1. The connecting electrode ZM overlaps the gate electrode GL1 and the oxide semiconductor layer OS and contacts the oxide semiconductor layer OS in the opening ZCON not overlapping the gate electrode GL1 in a plan view. The pixel electrode PTCO overlaps the gate electrode GL1, the oxide semiconductor layer OS, and the connecting electrode ZM and is connected to the connecting electrode ZM in the opening PCON overlapping the gate electrode GL1 in a plan view.

The pixel electrode PTCO of the first pixel provided on the upper side in FIG. 11 overlaps the oxide semiconductor layer OS of the first pixel and the oxide semiconductor layer OS of the second pixel provided on the lower side of the first pixel in a plan view. Further, the pixel electrode PTCO of the first pixel also overlaps a part of the oxide semiconductor layer OS of the fourth pixel in a plan view.

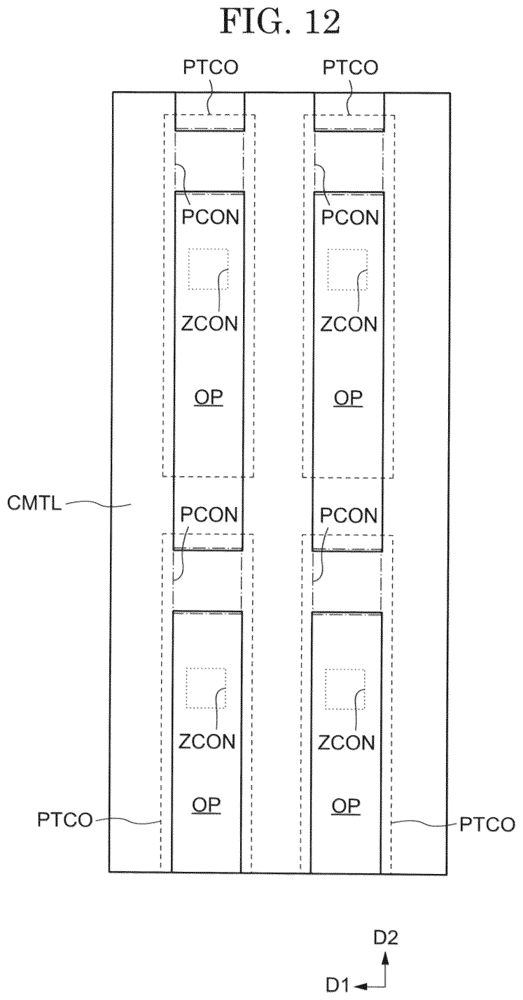

As shown in FIG. 12, the common auxiliary electrode CMTL is provided in a grid shape so as to surround the periphery of a pixel region. That is, the common auxiliary electrode CMTL is provided commonly for multiple pixels. In other words, the common auxiliary electrode CMTL has an opening OP. The opening OP is provided to expose the pixel electrode PTCO. A pattern of the opening OP is provided inside the pattern of the pixel electrode PTCO. A region provided with the opening OP corresponds to a display region. That is, the opening ZCON is included in the display region. The display region means a region in which a user can see light from a pixel. For example, a frame region that is shielded by a metal layer and unperceivable to the user is not included in the display region. That is, the above display region may be referred to as a “translucent region (or opening region).”

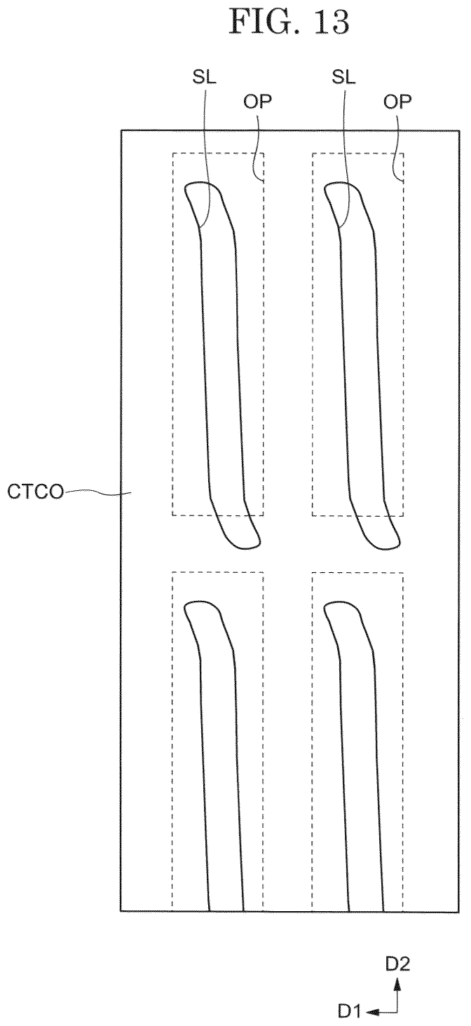

As shown in FIG. 13, the common electrode CTCO is provided commonly for multiple pixels. A slit SL is provided in a region corresponding to the above opening OP. The slit SL has a curved shape (longitudinally long S-shape). A tip of the slit SL has a shape in which a width orthogonal to an extending direction of the tip is reduced. Referring to FIG. 1 and FIG. 13, the common electrode CTCO has the slit SL at a position facing the pixel electrode PTCO.

### [1-5. Connection Structure Between Oxide Semiconductor Layer OS and Connection Electrode ZM]

Referring to FIG. 14 and FIG. 15, the oxide semiconductor layer OS and the connection electrode ZM in the opening ZCON will be described. In FIG. 14, for convenience of explanation, the light-shielding layer LS is shown as a single layer. The transistor Tr1 in FIG. 14 is the same as the transistor Tr1 in FIG. 1. Therefore, a description that overlaps the description of FIG. 1 will be omitted. In a lower part of FIG. 14, an entire structure of the transistor Tr1 is shown, and in an upper part of FIG. 14, a partially enlarged view of a region surrounded by a dotted square line of the transistor Tr1 shown in the lower part is shown.

As shown in FIG. 15, the connection electrode ZM exceeds a pattern end of the oxide semiconductor layer OS in an opposite direction to the direction D2 (direction D2′). Further, in the direction D2′, the opening ZCON exceeds the pattern end of the oxide semiconductor layer OS and a pattern end of the connection electrode ZM. In other words, the pattern end of the oxide semiconductor layers OS and the pattern end of the connection electrode ZM in the direction D2′ each overlap the opening ZCON in the plan view. Therefore, as shown in FIG. 14, the connection electrode ZM is in contact with the insulating layer IL1 outside the pattern of the oxide semiconductor layer OS beyond the pattern end of the oxide semiconductor layer OS in the direction D2′. In other words, the connection electrode ZM is in contact with the upper surface and a side surface of the oxide semiconductor layer OS at the pattern end of the oxide semiconductor layer OS in the direction D2′. Again in other words, the connection electrode ZM covers the pattern end of the oxide semiconductor layer OS at the bottom of the opening ZCON. The pattern end of the connection electrode ZM in the direction D2′ is present at the bottom of the opening ZCON, and the insulating layer IL1 is exposed from the connection electrodes ZM at the bottom of the opening ZCON.

The insulating layer IL1 arranged below the oxide semiconductor layer OS is thinned by etching the oxide semiconductor layer OS and the connection electrodes ZM. Therefore, in the plan view, thicknesses of the insulating layer IL1 in these regions differ from each other in the case where the insulating layer IL1 overlapping the opening ZCON is divided into an OS region overlapping the oxide semiconductor layer OS, a ZM region that does not overlap the oxide semiconductor layer OS but overlaps the connection electrode ZM, and an NO region that does not overlap either the oxide semiconductor layer OS or the connection electrode ZM. Specifically, the thickness of the insulating layer IL1 in the ZM region is smaller than the thickness of the insulating layer IL1 in the OS region. Likewise, the thickness of the insulating layer IL1 in the NO region is smaller than the thickness of the insulating layer IL1 in the ZM region. With the configuration described above, since the insulating layer IL1 and the insulating layer IL4 are in contact with each other at the bottom of the opening ZCON, adhesion between the insulating layer IL1 and the insulating layer IL4 is improved.

In other words, the thickness of the insulating layer IL1 in the ZM region overlapping the connection electrode ZM without overlapping the oxide semiconductor layer OS in the opening ZCON in the plan view is smaller than the thickness of the insulating layer IL1 in the OS region overlapping the oxide semiconductor layer OS in the opening ZCON in the plan view. Similarly, the thickness of the insulating layer IL1 in the NO region that does not overlap either the oxide semiconductor layer OS or the connection electrode ZM in the opening ZCON in the plan view is smaller than the thickness of the insulating layer IL1 in the ZM region overlapping the connection electrode ZM without overlapping the oxide semiconductor layer OS in the opening ZCON in the plan view.

As described above, in the cross-sectional view, the insulating layer IL1 inside the opening ZCON has a stepped shape. A step portion ST1 is formed between the ZM region and OS region. A step portion ST2 is formed between the NO region and ZM region. The step portion ST1 may be referred to as a “first step portion.” The step portion ST2 may be referred to as a “second step portion.” The step portion ST1 is formed in a vicinity of the pattern end of the oxide semiconductor layer OS in the plan view. The step portion ST2 is formed in a vicinity of the pattern end of the connection electrode ZM in the plan view. The connection electrode ZM covers the stepped portion ST1. A portion of the insulating layer IL1 is exposed from the connection electrode ZM in the step portion ST2.

As shown in FIG. 15, in the plan view, the connection electrode ZM is present inside the pattern of the light-shielding layer LS. In other words, as shown in FIG. 14, a pattern end of the light-shielding layer LS is located in the direction D2′ from the pattern end of the connection electrode ZM.

Conventionally, in order to realize a high-definition display device, measures have been taken to prevent the aperture ratio of a pixel from decreasing as a result of reducing the pixel size. For example, an oxide semiconductor layer having a light-transmitting property is used as a semiconductor layer functioning as a channel, and a transparent conductive layer such as ITO (Indium Tin Oxide) is used as a connection electrode connected to the oxide semiconductor layer.

On the other hand, in the process of realizing the embodiment according to the present invention, it has been found that in the case where ITO is used as the connection electrode, the initial properties of the transistor Tr1 may deteriorate. Specifically, in the transistor Tr1 according to the present embodiment, a transistor in which the connection electrode ZM is replaced from a metal layer to ITO may have a large variation in initial properties. More specifically, in an N-type transistor in which ITO is used as the connection electrode and an oxide semiconductor layer is used as the semiconductor layer, a threshold voltage in Id-Vg characteristics tends to shift in a negative direction.

The above phenomena are considered to be caused by water passing through ITO. That is, in the case where an organic resin is used as the insulating layer IL4, it is considered that the above phenomena occur due to the fact that water contained in the insulating layer IL4 passes through the connection electrode ZM (ITO) to reach the oxide semiconductor layer OS and oxygen vacancies are formed in the oxide semiconductor layer OS. This problem is a newly recognized problem in the process leading to the present invention, and is not a problem that has been recognized before.

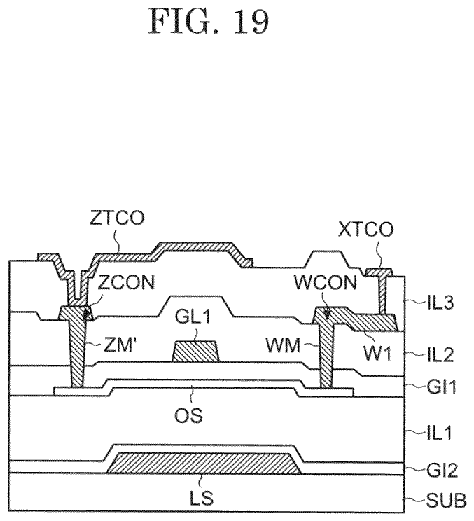

FIG. 19 is a cross-sectional view showing a structure of a semiconductor device according to a comparative example. As shown in FIG. 19, in a conventional configuration (comparative example), by providing a connection electrode ZM′ formed of a metal layer between the oxide semiconductor layer OS and a connection electrode ZTCO (transparent conductive layer), the phenomena described above can be suppressed. However, light is blocked by the metal layer used as the connection electrode ZM′, so that an aperture ratio is lowered.

Further, in the case where the opening ZCON is formed, it is difficult to provide the opening ZCON inside the pattern of the light-shielding layer LS in the plan view in consideration of an offset amount (a distance from the gate electrode GL1 in consideration of alignment deviation when forming the pattern of the opening ZCON) and a processing size of the opening ZCON with respect to the pattern of the gate electrode GL1. Therefore, in the plan view, at least a portion of the opening ZCON is formed on the outer side of the pattern of the light-shielding layers LS. For example, in the case where a portion of the opening ZCON is formed outside the pattern of the light-shielding layer LS in the plan view, when the connection electrode ZM′ is to be formed so that a pattern of the connection electrode ZM′ is located inside the pattern of the light-shielding layer LS, the upper surface of the oxide semiconductor layer OS arranged below the connection electrode ZM′ is exposed from the connection electrode ZM′ and is in contact with the insulating layer IL4.

If the oxide semiconductor layer OS is in contact with the insulating layer IL4, water contained in the insulating layer IL4 reaches the oxide semiconductor layer OS, oxygen vacancies are formed in the oxide semiconductor layer OS, and a threshold voltage of the transistor is shifted in the negative direction. Further, in order to reliably avoid the oxide semiconductor layer OS and the insulating layer IL4 from contacting each other, the oxide semiconductor layer OS needs to be prevented from being exposed from the connection electrode ZM′. Therefore, the pattern of the connection electrode ZM′ needs to be larger than the pattern of the opening ZCON. Therefore, there is a problem in that a light-shielded region becomes larger.

As described above, in the structure of the transistor according to the comparative example, the upper surface of the oxide semiconductor layer OS needs to be prevented from being exposed from the connection electrode ZM′ at the bottom of the opening ZCON. Therefore, the connection electrode ZM′ is formed in a region that does not overlap the light-shielding layer LS in the plan view, which causes a problem that the light-shielding region becomes larger.

On the other hand, according to the transistor Tr1 of the present embodiment, in a region overlapping the opening ZCON in the plan view, the pattern end of the oxide semiconductor layer OS is formed, and the upper surface of the oxide semiconductor layer OS and the pattern end of the oxide semiconductor layer OS are covered with the connection electrode ZM.

Further, it is possible to suppress light shielding caused by the connection electrode ZM by the pattern of the connection electrode ZM overlapping the pattern of the light-shielding layer LS in the plan view. In this case, since the connection electrode ZM is arranged so as to cover the end portion of the pattern of the oxide semiconductor layer OS, it is possible to prevent water from reaching the oxide semiconductor layer OS.

In the present embodiment, a width of the oxide semiconductor layer OS is larger than a width of the opening ZCON in the direction D1 in the plan view. That is, in the plan view, one side of the pattern of the oxide semiconductor layer OS overlaps the opening ZCON. However, the present invention is not limited to the above configuration. For example, the width of the oxide semiconductor layer OS may be smaller than the width of the opening ZCON in the direction D1 in the plan view. That is, three sides of the pattern of the oxide semiconductor layers OS may overlap the opening ZCON in the plan view.

### [1-6. Materials of Each Member of Display Device 10]

A rigid substrate having light transmittance and no flexibility, such as a glass substrate, a silica substrate, and a sapphire substrate can be used as the substrate SUB. On the other hand, in the case where the substrate SUB needs to have a flexibility, a flexible substrate containing a resin and having flexibility, such as a polyimide substrate, an acrylic substrate, a siloxane substrate, or a fluororesin substrate can be used as the substrate SUB. In order to improve the heat resistance of the substrate SUB, impurities may be introduced into the above resin.

General metal materials can be used as the gate electrodes GL1, GL2, the wirings W1, W2, the light-shielding layer LS, and the common auxiliary electrode CMTL. For example, aluminum (Al), titanium (Ti), chromium (Cr), cobalt (Co), nickel (Ni), molybdenum (Mo), hafnium (Hf), tantalum (Ta), tungsten (W), bismuth (Bi), and silver (Ag), or alloys or compounds thereof are used as members of these electrodes and the like. The above materials may be used in a single layer or a stacked layer as the members of the above electrodes and the like.

For example, a stacked structure of Ti/Al/Ti is used as the gate electrode GL1. In the present embodiment, the cross-sectional shape of a pattern end of the gate electrode GL1 having the above stacked structure is a forward taper shape.

General insulating materials can be used as the gate insulating layers GI1, GI2 and the insulating layers IL1 to IL5. For example, inorganic insulating layers such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), aluminum nitride (AlNₓ), and the like can be used as the gate insulating layers GI1, GI2 and the insulating layers IL1 to IL3, and IL5. Low-defect insulating layers can be used as these insulating layers. Organic insulating materials such as a polyimide resin, an acrylic resin, an epoxy resin, a silicone resin, a fluororesin, or a siloxane resin can be used as the insulating layer IL4. The above organic insulating materials may be used as the gate insulating layers GI1, GI2, and the insulating layers IL1 to IL3, IL5. The above materials may be used in a single layer or a stacked layer as a member of the insulating layer and the like.

SiOₓ with a thickness of 100 nm is used as the gate insulating layer GI1 as an example of the above insulating layer. SiOₓ/SiNₓ/SiOₓ with a total thickness of 300 nm to 700 nm is used as the insulating layer IL1. SiOₓ/SiNₓ with a total thickness of 60 nm to 150 nm is used as the gate insulating layer GI2. SiOₓ/SiNₓ/SiOₓ with a total thickness of 300 nm to 500 nm is used as the insulating layer IL2. SiOₓ (single layer), SiNₓ (single layer) or a stacked layer thereof with a total thickness of 200 nm to 500 nm is used as the insulating layer IL3. The organic layer with a thickness of 2 μm to 4 μm is used as the insulating layer IL4. SiNₓ (single layer) with a thickness of 50 nm to 150 nm is used as the insulating layer IL5.

The above SiOₓN_{y} and AlOₓN_{y} are silicone compounds and aluminum compounds containing nitrogen (N) in a smaller ratio (x>y) than oxygen (O). The above SiNₓO_{y} and AlNₓO_{y} are silicon compounds and aluminum compounds containing oxygen in a smaller ratio (x>y) than nitrogen.

A metal oxide having semiconductor characteristics can be used as the oxide semiconductor layer OS.

Although a detailed method for manufacturing the oxide semiconductor layer OS will be described later, the oxide semiconductor layer OS can be formed using a sputtering method. A composition of the oxide semiconductor layer OS formed by the sputtering method depends on a composition of a sputtering target. In this case, a composition of a metal element in the oxide semiconductor layer OS can be specified based on a composition of a metal element of the sputtering target.

A transparent conductive layer is used as the pixel electrode PTCO and the common electrode CTCO as described above. A mixture of ITO and a mixture of indium oxide and zinc oxide (IZO) can be used as the transparent conductive layer. Materials other than the above may be used as the transparent conductive layer.

As described above, in the case where a metal oxide layer is arranged between the oxide semiconductor layer OS and the insulating layer IL1, a metal oxide containing aluminum as the main component is used as the metal oxide layer. For example, an inorganic insulating layer such as aluminum oxide (AlOₓ), aluminum oxynitride (AlOₓN_{y}), aluminum nitride oxide (AlNₓO_{y}), and aluminum nitride (AlNₓ) is used as the metal oxide layer. The “metal oxide layer containing aluminum as the main component” means that the ratio of aluminum contained in the metal oxide layer is 1% or more of the total amount of the metal oxide layer. The ratio of aluminum contained in the metal oxide layer may be 5% or more and 70% or less, 10% or more and 60% or less, or 30% or more and 50% or less of the total amount of the metal oxide layer. The ratio may be a mass ratio or a weight ratio.

As described above, according to the transistor Tr1 of the present embodiment, it is possible to realize a semiconductor device having good electric properties without reducing the aperture ratio.

### 2. Second Embodiment

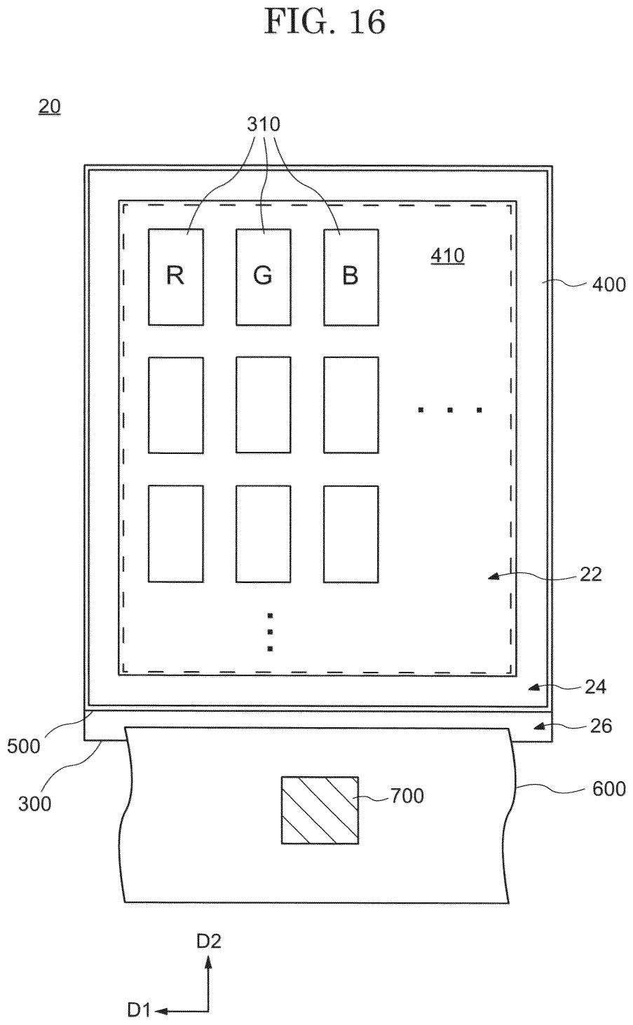

An entire configuration of the display device described in the first embodiment will be described with reference to FIG. 16 to FIG. 18.

### [2-1. Outline of Display Device 20]

FIG. 16 is a plan view showing an outline of a display device according to an embodiment of the present invention. As shown in FIG. 16, a display device 20 includes an array substrate 300, a seal part 400, a counter substrate 500, a flexible printed circuit board 600 (FPC 600), and an IC chip 700. The array substrate 300 and the counter substrate 500 are bonded by the seal part 400. Multiple pixel circuits 310 are arranged in a matrix in a liquid crystal region 22 surrounded by the seal part 400. The liquid crystal region 22 is a region overlapping a liquid crystal element 410 described later in a plan view. The liquid crystal region 22 is a region configured to contribute to display. The liquid crystal region 22 may be referred to as a “display region.” The transistor Tr1 is provided in the liquid crystal region 22 (display region).

A seal region 24 provided with the seal part 400 is a region around the liquid crystal region 22. The FPC 600 is provided in a terminal region 26. The terminal region 26 is a region where the array substrate 300 is exposed from the counter substrate 500 and provided outside the seal region 24. In addition, the exterior side of the seal region means outside the region provided with the seal part 400 and outside the region surrounded by the seal part 400. The IC chip 700 is provided on the FPC 600. The IC chip 700 supplies a signal for driving each pixel circuit 310. The seal region 24 or a region combined with the seal region 24 and the terminal region 26 is a region that surrounds the liquid crystal region 22 (display region). These regions may be referred to as a “frame region.” The transistor Tr2 is provided in the frame region.

### [2-2. Circuit Configuration of Display Device 20]

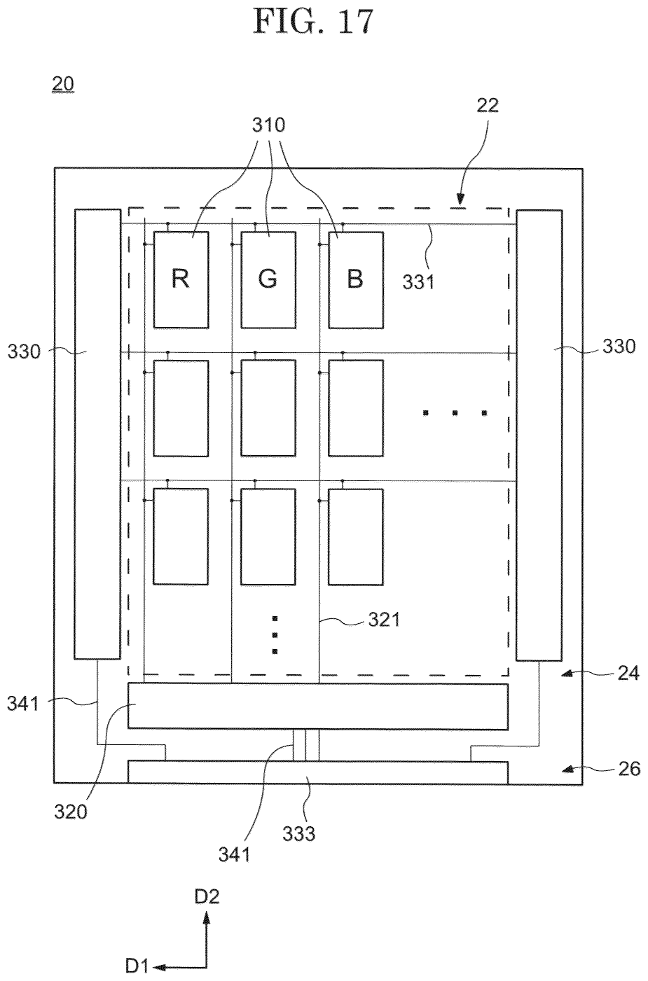

FIG. 17 is a block diagram showing a circuit configuration of a display device according to an embodiment of the present invention. As shown in FIG. 17, a source driver circuit 320 and the liquid crystal region 22 where the pixel circuit 310 is arranged are adjacent in the direction D1 (column direction), and the gate driver circuit 330 and the liquid crystal region 22 are adjacent in the direction D2 (row direction). The source driver circuit 320 and the gate driver circuit 330 are provided in the seal region 24 described above. However, the region where the source driver circuit 320 and the gate driver circuit 330 are provided is not limited to the seal region 24, and may be any region as long as it is outside the region provided with the pixel circuit 310.

A source wiring 321 extends in the direction D1 from the source driver circuit 320 and is connected to the multiple pixel circuits 310 arranged in the direction D1. A gate wiring 331 extends in the direction D2 from the gate driver circuit 330 and is connected to the multiple pixel circuits 310 arranged in the direction D2.

The terminal region 26 is provided with a terminal part 333. The terminal part 333 and the source driver circuit 320 are connected by a connecting wiring 341. Similarly, the terminal part 333 and the gate driver circuit 330 are connected by the connecting wiring 341. When the FPC 600 is connected to the terminal part 333, an external device to which the FPC 600 is connected and the display device 20 are connected, and each pixel circuit 310 provided in the display device 20 is driven by a signal from the external device.

The transistor Tr1 shown in the first embodiment is used for the pixel circuit 310. The transistor Tr2 shown in the first embodiment and the second embodiment is applied to the transistor included in the source driver circuit 320 and the gate driver circuit 330.

### [2-3. Pixel Circuit 310 of Display Device 20]

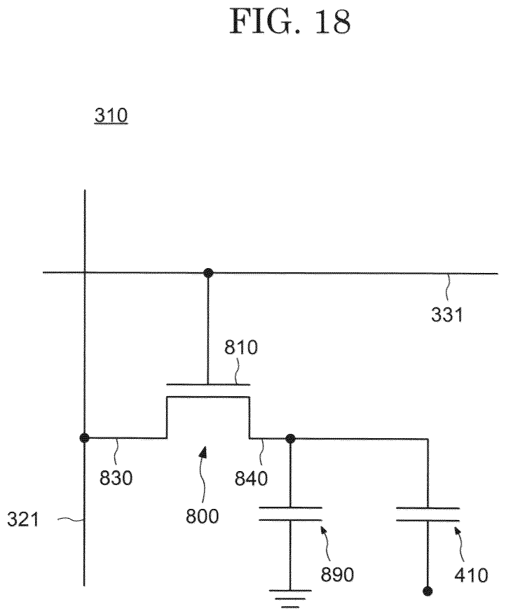

FIG. 18 is a circuit diagram showing a pixel circuit of a display device according to an embodiment of the present invention. As shown in FIG. 18, the pixel circuit 310 includes elements such as a transistor 800, a storage capacitor 890, and the liquid crystal element 410. One electrode of the storage capacitor 890 is the pixel electrode PTCO and the other electrode is the common electrode CTCO. Similarly, one electrode of the liquid crystal element 410 is the pixel electrode PTCO and the other electrode is the common electrode CTCO. The transistor 800 includes a first gate electrode 810, a first source electrode 830, and a first drain electrode 840. The first gate electrode 810 is connected to the gate wiring 331. The first source electrode 830 is connected to the source wiring 321. The first drain electrode 840 is connected to the storage capacitor 890 and the liquid crystal element 410. The transistor Tr1 shown in the first embodiment is applied to the transistor 800 shown in FIG. 18. In the present embodiment, for convenience of explanation, although 830 is referred to as a source electrode and 840 is referred to as a drain electrode, the function of each electrode as a source and a drain may be interchanged.

Each of the embodiments described above as an embodiment of the present invention can be appropriately combined and implemented as long as they do not contradict each other. Further, the addition, deletion, or design change of components, or addition, omission, or condition change of processes as appropriate by those skilled in the art based on each embodiment are also included in the scope of the present invention as long as they are provided with the gist of the present invention.

It is understood that, even if the effect is different from those provided by each of the embodiments described above, the effect obvious from the description in the specification or easily predicted by persons ordinarily skilled in the art is apparently derived from the present invention.

What is claimed is:

1. A semiconductor device comprising:
an oxide semiconductor layer having a pattern;
a gate electrode facing the oxide semiconductor layer;
a gate insulating layer provided between the oxide semiconductor layer and the gate electrode;
a first insulating layer provided above the gate electrode and having a first opening overlapping a pattern edge portion of the oxide semiconductor layer in a plan view; and
a first electrode provided above the first insulating layer and inside the first opening, and contacting the oxide semiconductor layer so as to cover the pattern edge portion of the oxide semiconductor layer in a bottom part of the first opening.

2. The semiconductor device according to claim 1, wherein the first electrode is a metal.

3. The semiconductor device according to claim 1, wherein the first electrode is in contact with an upper surface and a side surface of the oxide semiconductor layer in the pattern edge portion of the oxide semiconductor layer.

4. The semiconductor device according to claim 1,
further comprising a light shielding layer provided below the oxide semiconductor layer,
wherein the first electrode exists inside a pattern of the light shielding layer in a plan view.

5. The semiconductor device according to claim 3,
further comprising:
a light shielding layer provided below the oxide semiconductor layer; and
a second insulating layer provided between the light shielding layer and the oxide semiconductor layer,
wherein the first electrode is in contact with the second insulating layer outside the pattern of the oxide semiconductor layer in a plan view.

6. The semiconductor device according to claim 5, wherein
the second insulating layer includes a first step portion near the pattern edge portion of the oxide semiconductor layer in a plan view, and
the first electrode covers the first step portion.

7. The semiconductor device according to claim 6, wherein
a pattern edge portion of the first electrode overlaps the first opening in a plan view,
the second insulating layer includes a second step portion near a pattern edge portion of the first electrode in a plan view, and
the second insulating layer is exposed from the first electrode in the second step portion.

8. The semiconductor device according to claim 1, further comprising:
a third insulating layer provided between the first insulating layer and the oxide semiconductor layer, and having a second opening positioned inside the first opening and a pattern of the oxide semiconductor layer in a plan view; and
a second electrode provided between the third insulating layer and the first insulating layer, and provided inside the second opening.

9. The semiconductor device according to claim 8, wherein the second electrode is a metal.

10. The semiconductor device according to claim 5, wherein
a thickness of the second insulating layer in a region not overlapping the oxide semiconductor layer and overlapping the first electrode in the first opening in a plan view is smaller than a thickness of the second insulating layer overlapping the oxide semiconductor layer in the first opening.

11. The semiconductor device according to claim 10, wherein
a thickness of the second insulating layer in a region not overlapping both the oxide semiconductor layer and the first electrode in the first opening in a plan view is smaller than a thickness of the second insulating layer in a region not overlapping the oxide semiconductor layer and overlapping the first electrode in the first opening.
